(19) United States
(12) Patent Application Publication
(10) Pub. No.: US 2009/0249621 A1
(43) Pub. Date: Oct. 8, 2009

(54) METHOD FOR MAKING A MINIATURIZED DEVICE IN VOLUME

(76) Inventors: Michel Rochat, Lussy-sur-Morges (CH); Lionel Lemaire, Romanel-sur-Morges (CH)

Correspondence Address: NEXSEN PRUET, LLC, PO DRAWER 2426, COLUMBIA, SC, 29202-2426, US

(21) Appl. No.: 11/721,650

(22) PCT Filed: Nov. 30, 2005
(86) PCT No.: PCT/EP05/56336

§ 371 Date: Jun. 13, 2007

(30) Foreign Application Priority Data
Dec. 17, 2004 (EP) 04405782.6

(51) Int. Cl. H05K 3/02

(52) U.S. Cl. 29/847

(57) ABSTRACT

The invention concerns a method for making a miniaturized device in volume comprising at least one component and its connection integrated in a support matrix. Said matrix is formed by a deposition technique of the direct writing type, which consists in selectively depositing successive layers of material in fluid form.

### BACKGROUND OF THE INVENTION

1) Field of Invention

The present invention relates to the field of assembling microtechnical components. It relates more particularly to a process for producing a miniaturized volume device having an electrical function and/or an optical function and/or a fluid function, that is to say a heterogeneous device.

The invention is particularly advantageously applicable in the production of devices intended for chemical or biological analyses as described, for example, in document WO 03/035386. Such miniaturized heterogeneous devices are designed for a single or multiple use and are employed, for example, for medical diagnostics or for implantation in the human body.

2) Description of Related Art

In the microtechnical field, the aim of most assembly technologies is to combine and interconnect, on one and the same substrate, the largest possible number of components at the least cost, while minimizing the final overall size.

The densification of components was originally in plane densification. At the present time, it has become increasingly in volume densification, that is by stacking components.

One method consists in assembling the components on an initially flat flexible substrate and then, by folding, in forming a stack and obtaining a module of generally parallelepipedal shape. Another method consists in stacking rigid substrates provided with metallizations on the edge so as to obtain connections between the various layers, and then in laminating them in order to form a monolithic assembly.

However, these technologies are limited by the minimum width of the conducting tracks (currently of the order of 100 microns) which is a barrier to greater densification of the devices. Moreover, the production of substrates and the assembly of components constitute two separate operations, giving rise to a number of problems in respect of provisioning and logistics.

Finally, it should be pointed out that these processes are poorly suited to the integration of optic or fluidic elements, such as waveguides, optical microspectrometers or microfluidic channels. However, these elements, combined with electronic components, are becoming increasingly employed within complex heterogeneous devices and especially for medical and biomedical applications.

One example of an already existing approach for producing these heterogeneous devices is the “PCB” process.

The “PCB” approach, as described in the abovementioned document, makes use of the printed circuit technology for the production, on inexpensive substrates, of complex devices integrating optical or fluidic elements as well as electronic components. However this technology is relatively expensive and complex, since it involves many resist or copper deposition steps alternating with photolithography, etching or drilling steps requiring very specific know how and equipment.

Processes for producing complex devices involving techniques of depositing polymer layers and photolithography techniques are also described in documents U.S. Pat. No. 6,136,212 and U.S. Pat. No. 6,632,400. These processes suffer from the same drawbacks as the PCB approach.

Document US 2002/079219 describes a microfluidic device comprising a matrix provided with channels and reservoirs. Electrical components are formed in the matrix by ink jet printing.

### SUMMARY OF THE INVENTION

The object of the present invention is to propose a simple, compact and novel technology for producing heterogeneous volume devices, also using ink jet printing techniques and completely dispensing with processes employed in printed circuit technologies.

More precisely, the invention relates to a process for producing a miniaturized heterogeneous volume device comprising at least one component and its connection integrated within a support matrix. This process is characterized in that the matrix is formed by a deposition technique of the direct writing type, consisting in selectively depositing successive layers of material in fluid form.

Advantageously, said component or said connection may be:
either integrated into the matrix during production using a standard assembly technique, in a place left free of material and reserved for this purpose;
or formed directly within the matrix by said deposition technique;
or formed within the matrix by a step of depositing a sacrificial substance using said deposition technique, followed by a step of removing this substance.

It should be noted here that a method for forming fluidic connections on a substrate by wax based ink jet printing has already been described in document US 2004/0115861. However, that method does not allow production of the matrix of the volume device in question by direct writing, but only its microchannels.

### BRIEF DESCRIPTION OF THE DRAWING

Other features of the invention will become apparent from the description that follows, given in conjunction with the appended drawing in which:

FIG. 1 shows a perspective view of a heterogeneous device;

FIG. 2 is a stratified view of this same device on a carrier substrate; and

FIG. 3 is a sectional view on the line AA of the device in FIG. 1.

### DETAILED DESCRIPTION OF THE INVENTION

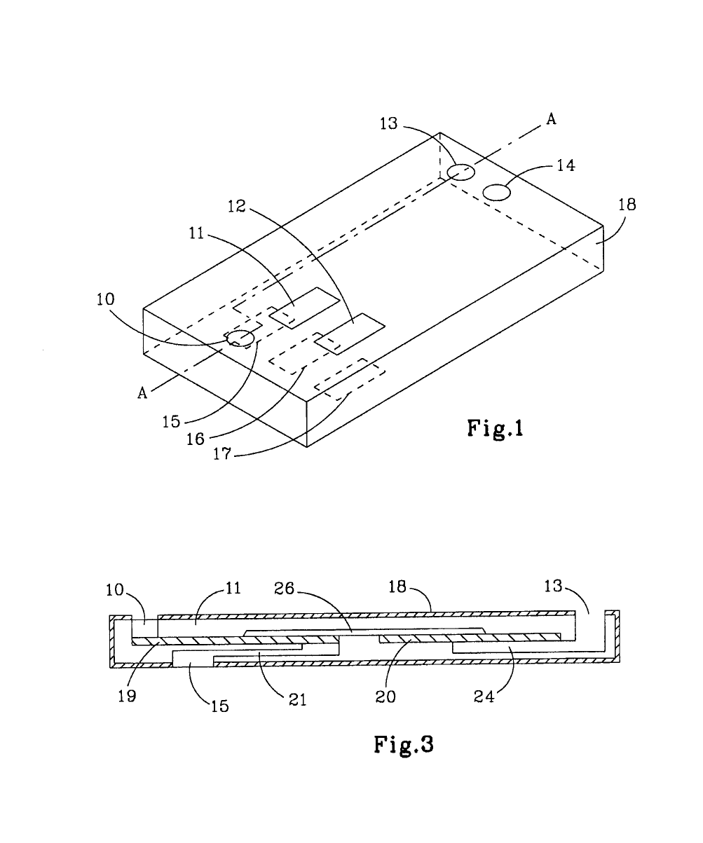

The heterogeneous device shown in FIG. 1 is an example of a device comprising volume integrated components connected together and accessible from the surface thanks to electrical, optical and fluidic connections. These components may for example be simple components, i.e. either electrical components, or optical components or fluidic components, such as resistive elements, optical gratings or chambers designed for mixing fluids. They may also be complex components, for example of the optoelectronic type, such as optical modulators, of the opto fluido electronic type, such as optical microspectrometers, or else of the fluido-electronic type. The connections intended for transporting an electrical or optical signal, or transporting material in fluid form, are typically electrical tracks, transparent segments or waveguides, or else horizontal or vertical channels.

The device shown in FIG. 1, of rectangular shape and having typical dimensions of 20 mm×10 mm, has, on its upper face, an optical entry port 10, two electrical connections 11 and 12, and a fluid inlet and a fluid outlet, respectively 13 and 14, which are intended for the circulation of a fluid to be analyzed. It also includes, on its lower face, three electrical connections 15, 16 and 17. If this device is intended to be implanted in the body, it is enclosed in a case 18 made of a biocompatible material well tolerated by the human organism.

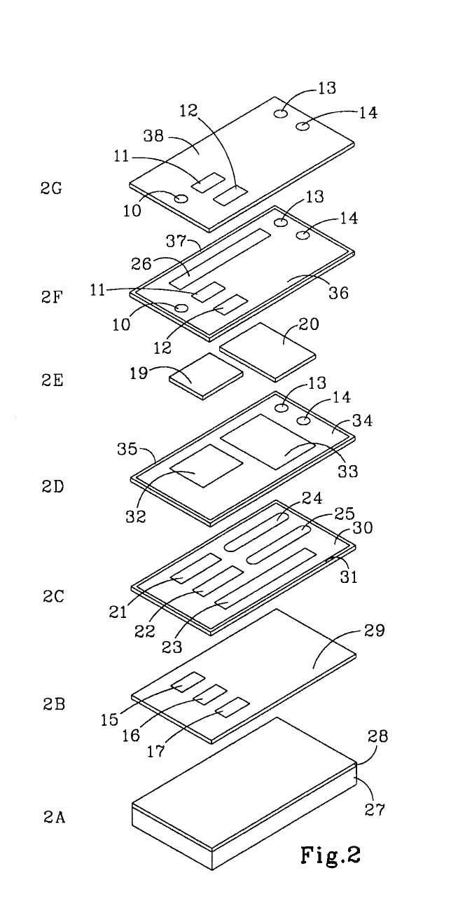

The stratified view of the device shown in FIG. 2 allows its structure and its production process to be understood. It includes, in its volume, two components 19 and 20 and their connections, these various elements being integrated within a one piece support matrix acting as a three dimensional substrate. The component 19 is of the optoelectronic type, its connections being of the optical and electrical type. The component 20 is of the opto fluido electronic type, its connections being of the optical, electrical and fluidic type.

Inside the volume, three conducting tracks 21, 22 and 23, two fluidic channels 24 and 25 and a waveguide 26 are intended for interconnecting the components. These various elements are furthermore connected to the outside via the two upper electrical contacts 11 and 12, the three lower electrical contacts 15, 16 and 17, the two fluidic connections 13 and 14 and the optical connection 10.

The electrical tracks 21 and 22 connect the component 19 to the lower electrical contacts 15 and 16 respectively. The electrical track 23 connects, in the same way, the component 20 to the lower electrical contact 17. The upper electrical contacts 11 and 12 connect the component 19. The optical entry port 10 provides the optical link between the component 19 and the outside, while the fluid inlet and outlet 13 and 14 are connected to the fluidic channels 24 and 25 respectively. The latter come into contact with the component 20 and make it possible for the fluid to be analyzed to flow through this component. Finally, the waveguide 26 acts as an optical link between the components 19 and 20, the component 20 not being directly connected to the optical entry port 10.

The technology used to produce this volume heterogeneous device is of the additive type. It consists, on the one hand, in depositing a quantity of a chosen material at the point where it is useful, so as to form the solid regions, such as the matrix, the waveguide or the electrical tracks, and on the other hand, in depositing a sacrificial material that is removed during a subsequent step, in order to form the empty regions, such as the fluidic channels.

The various deposition methods of the direct printing or writing type are, for example, ink jet printing, as described in document WO 02/47447 A1, micro dispensing and laser printing, more commonly known as laser direct writing.

Ink jet printing consists in ejecting fine droplets of a material to be deposited on to a substrate, in a controlled manner, with great precision, using nozzles with a very small diameter (less than 50 microns). Systems having several heads or multiple heads are used to dispense various materials. Micro dispensing uses a micropipette or a capillary moving near a substrate, so as to deposit material in liquid form. Finally, laser direct writing makes it possible to vaporize a solid in the area of a substrate where it will be deposited.

The materials used may be polyimides for the nonconductive parts, conductive polymers or conductive inks for the electrically conductive parts, polymers of optical quality for the waveguides, and sacrificial materials for the microfluidic channels.

The material is deposited by successive passes on a carrier substrate possessing a sacrificial layer, the elimination of which will allow, at the end of the process, to separate the device from the substrate. The layers, which typically have a thickness of 1 to 500 microns, are superposed one on top of another, thus creating the volume of the device. The various elements present in the device are either directly produced by direct writing or integrated into the device during deposition by a standard method of assembly.

The stratified view of the heterogeneous device shown in FIG. 2 illustrates one example of a sequence for producing such a device.

### FIG. 2A

The first production step consists in providing a carrier substrate 27 covered with a sacrificial layer 28, such as an aluminum layer. The substrate may for example be a circular silicon wafer or glass plate 20 cm in diameter, on which several devices are produced simultaneously.

### FIG. 2B

A layer 29, with a thickness of about 20 microns, made of a biocompatible polymer intended to form the case 18 of the device, and the three electrical contacts 15, 16, 17 are deposited on the sacrificial layer 28 by direct writing. A conductive polymer or a conductive ink is used to produce the electrical contacts.

### FIG. 2C

A third step consists in depositing the conducting tracks 21, 22 and 23 by direct writing and in forming the fluidic channels 24 and 25 within the support matrix. To do this, a polyimide support matrix layer 30 is deposited by direct writing at the same time as the conducting tracks 21, 22 and 23. The fluidic channels 24 and 25, which are horizontal spaces devoid of material, are formed by depositing a sacrificial material at their locations. This material would be removed during a subsequent step of the production process. A layer 31 of a biocompatible polymer intended to form the case 18 of the device is also deposited all around the support matrix layer 30, over a width of 50 to 100 microns.

### FIG. 2D

Places 32 and 33 intended to receive the components 19 and 20 are formed and the fluidic connections 13 and 14 are initiated. To do this, a support matrix layer 34, with a thickness corresponding to the thickness of the components 19 and 20, i.e. 100 to 500 microns, is deposited by direct writing over the entire surface apart from the places 32 and 33 reserved for the components. A sacrificial polymer is likewise deposited in two circular spaces emerging in the fluidic channels 24 and 25 so as to form the fluidic connections 13 and 14. As in the preceding step, a layer 35 of a biocompatible polymer intended to form the case of the device is deposited all around the support layer 34, over a width of 50 to 100 microns.

### FIG. 2E

The components 19 and 20 are placed in the openings 32 and 33 using a standard assembly technology.

### FIG. 2F

A support matrix layer 36 is deposited by direct writing at the same time as the electrical contacts 11 and 12, the waveguide 26 and the optical entry port 10. The latter two connections are made of a polymer of optical quality, the refractive index of which is different from the index of the support matrix. A sacrificial polymer is deposited at the place of the fluidic connections 13 and 14. As previously, a layer 37 of a biocompatible polymer is deposited all around the support layer 36.

At this point in the production of the device, it is necessary to remove the sacrificial material, typically polypropylene carbonate (PPC) or polyethylene carbonate (PEC), forming the fluidic channels 24 and 25 and the fluidic connections 13 and 14. This material is generally removed by pyrolysis, allowing complete thermal decomposition without any residue. After the sacrificial material has disappeared, the fluidic channels and connections appear as empty spaces within the support matrix.

### FIG. 2G

In a seventh step, a layer 38 with a thickness of about 20 microns of a biocompatible polymer intended to form the case 18 of the device is deposited by direct writing. Only the places for the fluidic connections 13 and 14, the optical connection 10 and the electrical contacts 11 and 12 are left free of material.

Lastly, a final operation consists in removing the sacrificial layer 28 so as to separate the device from its mechanical support 27. This operation is carried out for example by anodically dissolving the aluminum.

FIG. 3 shows in cross section the one piece device finally obtained.

The production sequence thus presented results in one embodiment of the heterogeneous device shown in FIGS. 1 and 2 produced by direct writing. In this embodiment, the connections such as the electrical tracks, the fluidic channels, the waveguide or the optical entry port are produced directly within the matrix by direct writing. However, it would be conceivable to use attached elements in order to form these connections and to integrate them within the matrix by a standard method of assembly. The electrical connections could be simple metal strips, the fluidic channels hollow tubes and the optical connections elements of a transparent material or a material having a specified refractive index.

In the same way, in the embodiment presented, the components 19 and 20 integrated into the device are complex components that are placed in the matrix by a standard method of assembly, not being able to be formed by direct writing. It would however be possible to form simple components, such as resistive elements, optical gratings or fluidic chambers, or even more complex components of the integrated circuit type based on polymer materials, in the matrix by direct writing.

Thus, most of the elements integrated into the matrix and forming the active part of the one piece device may be either produced by direct writing or placed inside the matrix by a standard method of assembly.

Thus a process is proposed for producing one piece compact heterogeneous devices consisting of a matrix and various elements, making it possible, thanks to the use of a direct writing deposition technique:
to form a three dimensional one piece matrix providing the device with rigidity and protecting said elements;
to integrate, within this matrix, electrical and/or optical and/or fluidic components; and
to connect these various components together or to the outside thanks to the integration of optical, fluidic or electrical connections within the matrix.

This technique is particularly advantageous since it furthermore makes it possible to completely dispense with deposition/masking/etching sequences that are indispensable in the PCB technology.

1-25. (canceled)

26. A process for producing a miniaturized heterogeneous volume device comprising at least one component and its connection integrated within a support matrix, wherein said matrix is formed by a deposition technique of a direct writing type comprising selectively depositing successive layers of material in fluid form.

27. The process as claimed in claim 26, wherein said component is integrated into the matrix during production by using a standard assembly technique in a place left free of material and reserved for this purpose.

28. The process as claimed in claim 26, wherein said component is formed directly within the matrix by said deposition technique.

29. The process as claimed in claim 26, wherein said component is formed within the matrix by a step of depositing a sacrificial substance using said deposition technique, followed by a step of removing said substance.

30. The process as claimed in claim 26, wherein said connection is integrated into the matrix during production by using a standard assembly technique in a place left free of material and reserved for this purpose.

31. The process as claimed in claim 26, wherein said connection is formed within the matrix by said deposition technique.

32. The process as claimed in claim 26, wherein said connection is formed within the matrix by a step of depositing a sacrificial substance using said deposition technique, followed by a step of removing this substance.

33. The process as claimed in claim 26, wherein the material constituting said matrix is a nonconductive polymer.

34. The process as claimed in claim 26, wherein the material constituting said connection or said component, or both said connection and said component, is a conductive polymer.

35. The process as claimed in claim 26, wherein the material constituting said connection or said component, or both said connection and said component, is a conductive ink.

36. The process as claimed in claim 26, wherein the material constituting said connection or said component, or both said connection and said component, is an optical polymer.

37. The process as claimed in claim 29, wherein said sacrificial substance is a polycarbonate.

38. The process as claimed in claim 26, wherein said deposition technique is ink jet printing.

39. The process as claimed in claim 26, wherein said deposition technique is laser printing by evaporation of a solid material.

40. The process as claimed in claim 26, wherein said deposition technique is micro dispensing.

41. The process as claimed in claim 26, wherein said material is deposited on a carrier substrate covered with a layer of sacrificial substance, the removal of which allows the device to be separated from said substrate.

42. The process as claimed in claim 32, wherein said sacrificial substance is a polycarbonate.

43. The process as claimed in claim 28, wherein said deposition technique is ink jet printing.

44. The process as claimed in claim 28, wherein said deposition technique is laser printing by evaporation of a solid material.

45. The process as claimed in claim 28, wherein said deposition technique is micro dispensing.
